(19) United States
(12) Patent Application Publication
(10) Pub. No.: US 2018/0175004 A1
(43) Pub. Date: Jun. 21, 2018

(54) THREE DIMENSIONAL INTEGRATED CIRCUIT PACKAGE AND METHOD FOR MANUFACTURING THEREOF

(71) Applicant: NANYA TECHNOLOGY CORPORATION, TAOYUAN CITY (TW)

(72) Inventor: Po-Chun LIN, Changhua County (TW)

(21) Appl. No.: 15/382,732

(22) Filed: Dec. 18, 2016

(51) Int. Cl. H01L 25/065; H01L 23/31; H01L 23/498; H01L 25/00; H01L 21/48

(52) U.S. Cl. CPC H01L 25/0657; H01L 23/3128; H01L 2225/06541; H01L 25/50; H01L 21/4853; H01L 23/49816

(57) ABSTRACT

A three dimensional integrated circuit (3DIC) package includes a redistribution layer, a plurality of semiconductor chips and a plurality of electrical bumpers. The redistribution layer has a first surface and a second surface. The redistribution layer has a passivation material. The semiconductor chips vertically and sequentially stacked on the first surface. The electrical bumpers are disposed on the second surface and are electrically connected to the semiconductor chips through the redistribution layer.

### BACKGROUND

### Technical Field

The present disclosure relates to a three dimensional integrated circuit (3DIC) package.

### Description of Related Art

The semiconductor industry continues to improve the integration density of various electronic components (e.g., transistors, diodes, resistors, capacitors, etc.) by continual reductions in minimum feature size, which allows more components to be integrated into a given area. In some applications, these smaller electronic components also require smaller semiconductor chips that utilize less area than semiconductor chips of the past.

In addition, the overall thickness of the package formed by the stacking of semiconductor chips also becomes a concern in the industry.

### SUMMARY

A technical aspect of the present disclosure is to provide a three dimensional integrated circuit (3DIC) package, which can effectively reduce the form factor of the 3DIC package.

According to an embodiment of the present disclosure, a 3DIC package includes a redistribution layer, a plurality of semiconductor chips and a plurality of electrical bumpers. The redistribution layer has a first surface and a second surface. The redistribution layer has a passivation material. The semiconductor chips are vertically and sequentially stacked on the first surface. The electrical bumpers are disposed on the second surface and are electrically connected to the semiconductor chips through the redistribution layer.

In one or more embodiments of the present disclosure, any adjacent two the semiconductor chips are stacked with a plurality of through-silicon via (TSV) connections connecting therebetween.

In one or more embodiments of the present disclosure, the electrical bumpers are solder balls.

In one or more embodiments of the present disclosure, at least one of the semiconductor chips is a memory chip.

In one or more embodiments of the present disclosure, the 3DIC package further includes a molding material. The molding material is disposed on the first surface. The semiconductor chips are at least partially embedded in the molding material.

According to an embodiment of the present disclosure, a three dimensional integrated circuit (3DIC) package includes a redistribution layer, a logic block, a plurality of semiconductor chips and a plurality of electrical bumpers. The redistribution layer has a first surface and a second surface. The redistribution layer has a passivation material. The logic block is disposed on the first surface. The semiconductor chips are vertically and sequentially stacked on the first surface. The electrical bumpers are disposed on the second surface and are electrically connected to the semiconductor chips through the redistribution layer and the logic block.

In one or more embodiments of the present disclosure, any adjacent two the semiconductor chips are stacked with a plurality of through-silicon via (TSV) connections connecting therebetween.

In one or more embodiments of the present disclosure, the electrical bumpers are solder balls.

In one or more embodiments of the present disclosure, at least one of the semiconductor chips is a memory chip.

In one or more embodiments of the present disclosure, the 3DIC package further includes a molding material. The molding material is disposed on the first surface. The semiconductor chips and the logic block are at least partially embedded in the molding material.

According to an embodiment of the present disclosure, a method for manufacturing a three dimensional integrated circuit (3DIC) package is provided. The method includes stacking a plurality of semiconductor chips vertically and sequentially on a carrier to form a stacking structure; applying a molding material on the carrier to surround the stacking structure; removing the carrier to expose a surface of the stacking structure; forming a redistribution layer on the exposed surface of the stacking structure; and disposing a plurality of electrical bumpers on the redistribution layer.

In one or more embodiments of the present disclosure, the step of forming of the redistribution layer includes forming the redistribution layer on a surface of the semiconductor chip exposing from the molding material.

In one or more embodiments of the present disclosure, the method further includes disposing a logic block on the carrier prior to the stacking. The step of stacking includes stacking the semiconductor chips vertically and sequentially on the logic block, so that the semiconductor chips and the logic block form the stacking structure.

In one or more embodiments of the present disclosure, the step of forming of the redistribution layer includes forming the redistribution layer on a surface of the logic block exposing from the molding material.

When compared with the prior art, the above-mentioned embodiments of the present disclosure have at least the following advantage:

(1) Structurally speaking, the redistribution layer is in direct contact with the stack of the semiconductor chips. Therefore, since the 3DIC package simply includes the redistribution layer disposed between the stack of the semiconductor chips and the electrical bumpers, the overall dimension and thus the form factor of the 3DIC package is effectively reduced.

(2) Structurally speaking, the logic block is in direct contact with the redistribution layer and the stack of the semiconductor chips. Therefore, since the 3DIC package simply includes the redistribution layer and the logic block disposed between the stack of the semiconductor chips and the electrical bumpers, the overall dimension and thus the form factor of the 3DIC package is effectively reduced.

### BRIEF DESCRIPTION OF THE DRAWINGS

The disclosure can be more fully understood by reading the following detailed description of the embodiments, with reference made to the accompanying drawings as follows:

FIG. 1 is a sectional view of a three dimensional integrated circuit (3DIC) package according to an embodiment of the present disclosure; and

FIG. 2 is a sectional view of a three dimensional integrated circuit (3DIC) package according to another embodiment of the present disclosure.

### DETAILED DESCRIPTION

Drawings will be used below to disclose embodiments of the present disclosure. For the sake of clear illustration, many practical details will be explained together in the description below. However, it is appreciated that the practical details should not be used to limit the claimed scope. In other words, in some embodiments of the present disclosure, the practical details are not essential. Moreover, for the sake of drawing simplification, some customary structures and elements in the drawings will be schematically shown in a simplified way. Wherever possible, the same reference numbers are used in the drawings and the description to refer to the same or like parts.

Unless otherwise defined, all terms (including technical and scientific terms) used herein have the same meanings as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

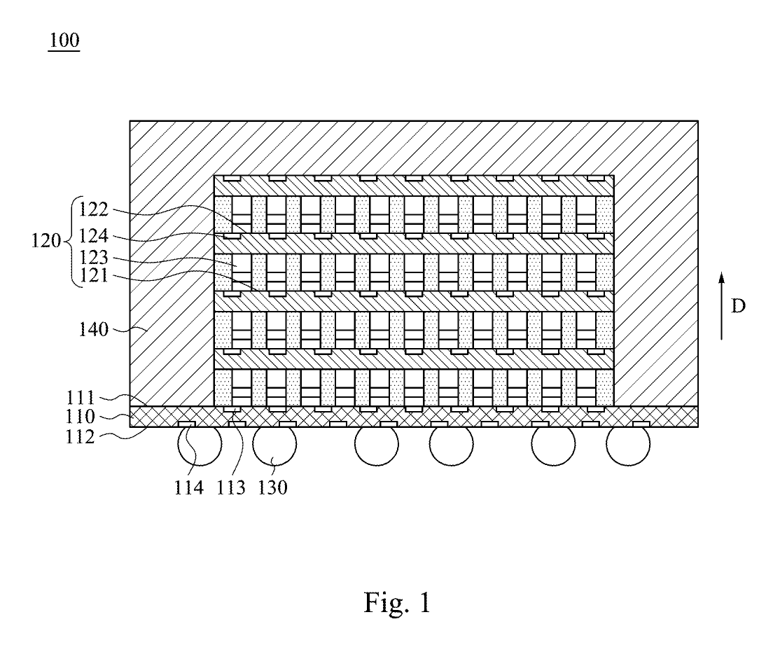

Reference is made to FIG. 1. FIG. 1 is a sectional view of a three dimensional integrated circuit (3DIC) package 100 according to an embodiment of the present disclosure. As shown in FIG. 1, a 3DIC package 100 includes a redistribution layer (RDL) 110, a plurality of semiconductor chips 120 and a plurality of electrical bumpers 130. The redistribution layer 110 has a first surface 111 and a second surface 112. In practice, the redistribution layer 110 can have a passivation material, such as silicon dioxide (SiO₂), silicon nitride (Si₃N₄), or polyimide (Pl). For example, since polyimide is a polymer of imide monomers, which has a high thermal resistance, the redistribution layer 110 has a high thermal resistance accordingly. On the other hand, in this embodiment, fiber such as glass fiber or material of resin is not included in the redistribution layer 110. The semiconductor chips 120 are vertically and sequentially stacked on the first surface 111. To be specific, the semiconductor chips 120 are stacked in a direction D away from the first surface 111 of the redistribution layer 110. The electrical bumpers 130 are disposed on the second surface 112 of the redistribution layer 110. The electrical bumpers 130 are electrically connected to the semiconductor chips 120 through the redistribution layer 110. In this embodiment, the electrical bumpers 130 can be solder balls. However, this does not intend to limit the present disclosure.

In other words, structurally speaking, the redistribution layer 110 is in direct contact with the stack of the semiconductor chips 120. Therefore, since the 3DIC package 100 simply includes the redistribution layer 110 disposed between the stack of the semiconductor chips 120 and the electrical bumpers 130, the overall dimension and thus the form factor of the 3DIC package 100 is effectively reduced.

In this embodiment, as shown in FIG. 1, the quantity of the semiconductor chips 120 is four. However, in other embodiments, for example, the quantity of the semiconductor chips 120 can be more than four or less than four according to the actual conditions.

To be more specific, in this embodiment, each of the semiconductor chips 120 has a third surface 121 and a fourth surface 122. The third surface 121 and the fourth surface 122 are opposite to each other. The third surface 121 of each of the semiconductor chips 120 is located between the first surface 111 of the redistribution layer 110 and the fourth surface 122 of the corresponding semiconductor chip 120. In addition, each of the semiconductor chips 120 includes a plurality of through-silicon vias (TSV) 123. The through-silicon vias 123 expose from the third surface 121 of each of the semiconductor chips 120. In practical applications, at least one of the semiconductor chips 120 can be a memory chip, such as a dynamic random-access memory (DRAM). However, this does not intend to limit the present disclosure.

Moreover, as shown in FIG. 1, in this embodiment, each of the semiconductor chips 120 has a plurality of connecting pads 124. The connecting pads 124 are located on the fourth surface 122 of the corresponding semiconductor chips 120. Moreover, the connecting pads 124 are electrically connected with the through-silicon via 123 of the same semiconductor chip 120. In addition, the connecting pads 124 are configured to be electrically connected with the through-silicon vias 123 exposing from the third surface 121 of the adjacent semiconductor chip 120. In practice, the connecting pads 124 can include electrically conductive material such as aluminum, copper or similar materials.

In other words, to be more specific, when the semiconductor chips 120 are vertically and sequentially stacked on the first surface 111, the semiconductor chips 120 are stacked with the through-silicon via 123 connections connecting therebetween.

On the other hand, in this embodiment, the redistribution layer 110 includes a plurality of first conductive features 113. The first conductive features 113 are exposed on the first surface 111 of the redistribution layer 110. In addition, the first conductive features 113 are configured to be electrically connected with the through vias 123 exposing from the third surface 121 of the adjacent semiconductor chip 120.

Furthermore, the redistribution layer 110 includes a plurality of second conductive features 114. The second conductive features 114 are exposed on the second surface 112 of the redistribution layer 110. In addition, the second conductive features 114 are configured to be electrically connected with the electrical bumpers 130. In this way, the semiconductor chips 120 and the electrical bumpers 130 are electrically connected through the first conductive features 113 and the second conductive features 114 of the redistribution layer 110.

In practical applications, as shown in FIG. 1, the 3DIC package 100 further includes a molding material 140. Structurally speaking, the molding material 140 is disposed on the first surface 111 of the redistribution layer 110. Meanwhile, the semiconductor chips 120 are at least partially embedded in the molding material 140.

During the manufacture of the 3DIC package 100 in this embodiment, the semiconductor chips 120 are first vertically and sequentially stacked on a carrier (not shown) to form a stacking structure. The relative position between the semiconductor chips 120 is fixed by thermal compressive bond between the semiconductor chips 120. Then, the molding material 140 is applied on the carrier to surround the stacking structure, such that the semiconductor chips 120 are at least partially embedded in the molding material 140. Afterwards, the carrier is moved to expose a surface of the stacking structure from the molding material 140, and the redistribution layer 110 is formed on the exposed surface of the semiconductor chip 120 previously in contact with the carrier. Then, the electrical bumpers 130 are disposed on the redistribution layer 110. Finally, individual pieces of the 3DIC packages 100 are formed by the process of singulation.

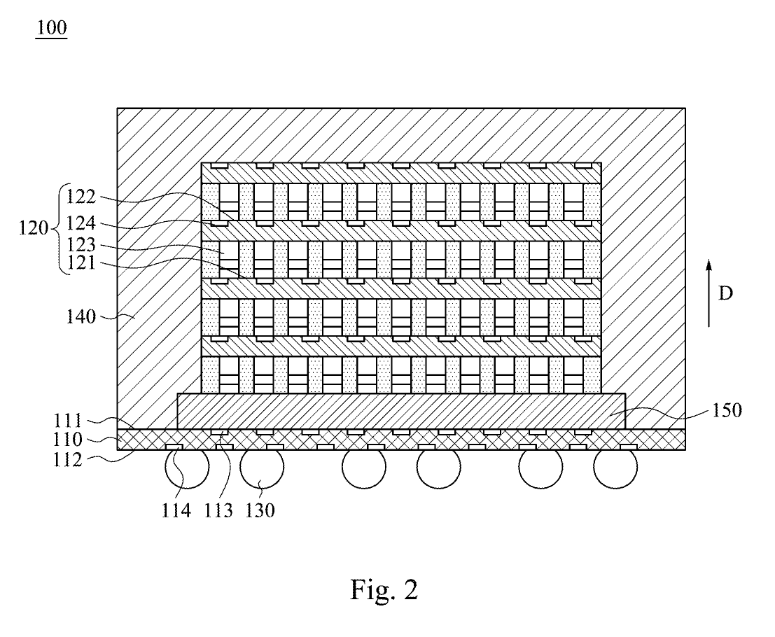

Reference is made to FIG. 2. FIG. 2 is a sectional view of a three dimensional integrated circuit (3DIC) package 100 according to another embodiment of the present disclosure. In this embodiment, the 3DIC package 100 further includes a logic block 150. Unlike the previous embodiment as shown in FIG. 1 that the redistribution layer 110 is in direct contact with the adjacent semiconductor chips 120, for this embodiment as shown in FIG. 2, the logic block 150 is disposed on the first surface 111 of the redistribution layer 110, and is located between the redistribution layer 110 and the semiconductor chips 120. In other words, the redistribution layer 110 and the adjacent semiconductor chip 120 are not in direct contact anymore. In practical applications, the logic block 150 has a logic circuit (not shown) therein.

On the other hand, structurally speaking, the logic block 150 is in direct contact with the redistribution layer 110 and the adjacent semiconductor chip 120. Therefore, since the 3DIC package 100 simply includes the redistribution layer 110 and the logic block 150 disposed between the stack of the semiconductor chips 120 and the electrical bumpers 130, the overall dimension and thus the form factor of the 3DIC package 100 is effectively reduced.

To be more specific, in this embodiment, the electrical bumpers 130 are disposed on the second surface 112 of the redistribution layer 110, and are electrically connected to the semiconductor chips 120 through the redistribution layer 110 and the logic block 150.

Furthermore, in this embodiment, as shown in FIG. 2, the semiconductor chips 120 and the logic block 150 are at least partially embedded in the molding material 140.

During the manufacture of the 3DIC package 100 in this embodiment, the logic block 150 is first disposed on a carrier (not shown) prior to the stacking of the semiconductor chips 120. Then, the semiconductor chips 120 are vertically and sequentially stacked on the logic block 150. In other words, the semiconductor chips 120 and the logic block 150 form the stacking structure together. Same as above, the relative position between the semiconductor chips 120 is fixed by thermal compressive bond between the semiconductor chips 120. Then, the molding material 140 is applied to surround the stacking structure of the semiconductor chips 120 and the logic block 150, such that the stacking structure of the semiconductor chips 120 and the logic block 150 are at least partially embedded in the molding material 140. Afterwards, the carrier is moved, and the redistribution layer 110 is formed on a surface of the logic block 150 exposing from the molding material 140. Then, the electrical bumpers 130 are disposed on the redistribution layer 110. Finally, individual pieces of the 3DIC packages 100 are formed by the process of singulation.

In conclusion, when compared with the prior art, the aforementioned embodiments of the present disclosure have at least the following advantage:

(1) Structurally speaking, the redistribution layer is in direct contact with the stack of the semiconductor chips. Therefore, since the 3DIC package simply includes the redistribution layer disposed between the stack of the semiconductor chips and the electrical bumpers, the overall dimension and thus the form factor of the 3DIC package is effectively reduced.

(2) Structurally speaking, the logic block is in direct contact with the redistribution layer and the stack of the semiconductor chips. Therefore, since the 3DIC package simply includes the redistribution layer and the logic block disposed between the stack of the semiconductor chips and the electrical bumpers, the overall dimension and thus the form factor of the 3DIC package is effectively reduced.

Although the present disclosure has been described in considerable detail with reference to certain embodiments thereof, other embodiments are possible. Therefore, the spirit and scope of the appended claims should not be limited to the description of the embodiments contained herein.

It will be apparent to the person having ordinary skill in the art that various modifications and variations can be made to the structure of the present disclosure without departing from the scope or spirit of the present disclosure. In view of the foregoing, it is intended that the present disclosure cover modifications and variations of the present disclosure provided they fall within the scope of the following claims.

1. A three dimensional integrated circuit (3DIC) package, comprising:
a redistribution layer having a first surface and a second surface, the redistribution layer having a passivation material;
a plurality of semiconductor chips vertically and sequentially stacked on the first surface, a combination of the redistribution layer and the passivation material having an upper surface that is wider than a width of each of the semiconductor chips; and
a plurality of electrical bumpers disposed on the second surface and electrically connected to the semiconductor chips through the redistribution layer.

2. The 3DIC package of claim 1, wherein any adjacent two the semiconductor chips are stacked with a plurality of through-silicon via (TSV) connections connecting therebetween.

3. The 3DIC package of claim 1, wherein the electrical bumpers are solder balls.

4. The 3DIC package of claim 1, wherein at least one of the semiconductor chips is a memory chip.

5. The 3DIC package of claim 1, further comprising a molding material disposed on the first surface, the semiconductor chips being at least partially embedded in the molding material.

6. A three dimensional integrated circuit (3DIC) package, comprising:
a redistribution layer having a first surface and a second surface, the redistribution layer having a passivation material;
a logic block disposed on the first surface;
a plurality of semiconductor chips vertically and sequentially stacked on the logic block, a combination of the redistribution layer and the passivation material having an upper surface that is wider than a width of each of the semiconductor chips; and
a plurality of electrical bumpers disposed on the second surface and electrically connected to the semiconductor chips through the redistribution layer and the logic block.

7. The 3DIC package of claim 6, wherein any adjacent two the semiconductor chips are stacked with a plurality of through-silicon via (TSV) connections connecting therebetween.

8. The 3DIC package of claim 6, wherein the electrical bumpers are solder balls.

9. The 3DIC package of claim 6, wherein one of the semiconductor chips is a memory chip.

10. The 3DIC package of claim 6, further comprising a molding material disposed on the first surface, the semiconductor chips and the logic block being at least partially embedded in the molding material.

11. A method for manufacturing a three dimensional integrated circuit (3DIC) package, comprising:
stacking a plurality of semiconductor chips vertically and sequentially on a carrier to form a stacking structure;
applying a molding material on the carrier to surround the stacking structure;
removing the carrier to expose a surface of the stacking structure;
forming a redistribution layer on the exposed surface of the stacking structure; and
disposing a plurality of electrical bumpers on the redistribution layer.

12. The method of claim 11, wherein the forming of the redistribution layer comprises:
forming the redistribution layer on a surface of the semiconductor chip exposing from the molding material.

13. The method of claim 11, further comprising:
disposing a logic block on the carrier prior to the stacking,
wherein the stacking comprising:
stacking the semiconductor chips vertically and sequentially on the logic block, so that the semiconductor chips and the logic block form the stacking structure.

14. The method of claim 13, wherein the forming of the redistribution layer comprises:
forming the redistribution layer on a surface of the logic block exposing from the molding material.
